(19) United States
(12) Patent Application Publication
(10) Pub. No.: US 2008/0023654 A1
(43) Pub. Date: Jan. 31, 2008

(54) METHOD OF REDUCING TRANSIENT WAFER TEMPERATURE DURING IMPLANTATION

(76) Inventors: Michael Graf, Belmont, MA (US); Louis P. Wainwright, Beverly, MA (US)

Correspondence Address: ESCHWEILER & ASSOCIATES, LLC;NATIONAL CITY BANK BUILDING, 629 EUCLID AVE., SUITE 1000, CLEVELAND, OH, 44114, US

(21) Appl. No.: 11/829,243

(22) Filed: Jul. 27, 2007

Related U.S. Application Data
(60) Provisional application No. 60/833,938, filed on Jul. 28, 2006.

(51) Int. Cl. H01J 37/08

(52) U.S. Cl. 250/492.21

(57) ABSTRACT

The present invention is directed to a method and apparatus for providing a uniform ion implantation in a single-workpiece two-dimensional mechanical scanning ion implantation system, wherein the transient temperature operating parameter is controlled based on mechanical rotation of the workpiece by a predetermined amount between two or more scans of the workpiece through a fixed ion beam. Rotating the workpiece between scans through the fixed ion beam allows for the transient temperature to decay sufficiently for more uniform ion implantation processes to proceed.

### REFERENCE TO RELATED APPLICATION

This application claims priority to and the benefit of U.S. Provisional Application Ser. No. 60/833,938 which was filed Jul. 28, 2006, entitled METHOD OF REDUCING TRANSIENT WAFER TEMPERATURE DURING IMPLANTATION, the entirety of which is hereby incorporated by reference as if fully set forth herein.

### FIELD OF THE INVENTION

The present invention relates generally to ion implantation systems, and more specifically to improved systems and methods for uniformly scanning a fixed ion beam relative to a translating workpiece, wherein a transient workpiece temperature is reduced.

### BACKGROUND OF THE INVENTION

In the manufacture of semiconductor devices and other products, ion implantation is used to dope semiconductor wafers, display panels, or other workpieces with impurities. Ion implanters or ion implantation systems treat a workpiece with an ion beam, to produce n-type or p-type doped regions, or to form passivation layers in the workpiece. When used for doping semiconductors, the ion implantation system injects a selected ion species to produce the desired extrinsic material, wherein implanting ions generated from source materials such as antimony, arsenic, or phosphorus results in n-type extrinsic material wafers, and implanting materials such as boron, gallium, or indium creates p-type extrinsic material portions in a semiconductor wafer.

Conventionally, ion implantation processes are performed in either a batch process, wherein multiple workpieces are processed simultaneously, or in a serial process, wherein a single workpiece is individually processed. Traditional high-energy or high-current batch ion implanters, for example, are operable to achieve a short ion beam line, wherein a large number of workpieces may be placed on a wheel or disk, and the wheel is simultaneously spun and radially translated through the ion beam, thus exposing surface areas of all of the workpieces to the ion beam at various times throughout the process. Processing batches of workpieces in such a manner, however, generally makes the ion implanter substantially large in size.

In a typical serial process, on the other hand, an ion beam is either scanned in a single axis across a stationary workpiece, the workpiece is translated in one direction past a fan-shaped, or scanned ion beam, or the workpiece is translated in generally orthogonal axes with respect to a stationary ion beam or “spot beam”. The process of scanning or shaping a uniform ion beam, however, generally requires a complex and/or long beam line, which is generally undesirable at low energies.

Translating the workpiece in generally orthogonal axes, however generally requires a uniform translation and/or rotation of either the ion beam or the workpiece in order to provide a uniform ion implantation across the workpiece. Furthermore, such a translation should occur in an expedient manner, in order to provide acceptable workpiece throughput in the ion implantation process. However, such a uniform translation and/or rotation can be difficult to achieve, due, at least in part, to substantial inertial forces associated with moving the conventional devices and scan mechanisms during processing.

In a conventional ion implantation system wherein the workpiece is moved relative to a fixed spot beam, the workpiece is generally translated in what is termed a scanning or “fast scan” direction, and a slower, generally orthogonal “slow scan” direction, wherein the workpiece is translated at least twice in opposing directions through the ion beam in the slow scan direction such that each scan of the workpiece through the spot beam in the fast scan direction at least partially overlaps the previous scans to provide a generally uniform ion implantation.

### SUMMARY OF THE INVENTION

The following presents a simplified summary of the invention in order to provide a basic understanding of some aspects of the invention. This summary is not an extensive overview of the invention, and is neither intended to identify key or critical elements of the invention nor to delineate the scope of the invention. Rather, the purpose of the summary is to present some concepts of the invention in a simplified form as a prelude to the more detailed description that is presented later.

The present invention is related to ion implantation systems and methods for performing ion beam implantation to a workpiece with a reduced workpiece operating temperature at the edges. The invention finds utility in a fixed beam ion implantation application and may be advantageously employed to mitigate incident temperature variations along a scan direction to improve implantation uniformity across a workpiece.

In accordance with an aspect of the invention, an ion implantation method for single workpiece implantation is provided for reducing the maximum temperatures reached on the surface of a workpiece and providing a more uniform temperature continuum along a scan axis than conventional systems. In one or more aspects of the present invention, the workpiece is rotated a first predetermined amount (e.g., approximately 180 degrees) after a first pass through the ion beam in a slow scan direction and prior to a second pass in the slow scan direction to mitigate excessive localized temperatures at the edge after passing along a scan axis. In one example, the workpiece rotated a second predetermined amount (e.g., approximately 90 degrees) after the second pass in the slow scan direction and prior to a third pass in the slow scan direction. After the third pass in the slow scan direction, the workpiece is again rotated the first predetermined amount and is passed through the ion beam for a fourth pass in the slow scan direction. Further, any number of additional rotations at various degrees of rotation, as well as any number of corresponding passes of the workpiece through the ion beam may be implemented in accordance with the present invention.

In accordance with another aspect of the invention, an ion implantation method for single workpiece implantation comprises a single workpiece implantation with at least two slow scans of a workpiece through a fixed ion beam and/or a ribbon beam intervened by a mechanical rotation of the workpiece between the at least two slow scans to ensure substantial temperature uniformity.

In accordance with still another aspect of the invention, an ion implantation system is provided that comprises an ion source, a mass analyzer, and an end station. The system further comprises a means for rotating the workpiece a predetermined amount between each slow scan pass of the workpiece past a fixed ion beam, so that the same leading edge is presented upon successive passes of the beam.

The following description and annexed drawings set forth in detail certain illustrative aspects and implementations of the invention. These are indicative of but a few of the various ways in which the principles of the invention may be employed.

### BRIEF DESCRIPTION OF THE DRAWINGS

FIG. 1 is a plan view of an exemplary ion implantation system according to one aspect of the present invention.

FIG. 2 is a plan view of an exemplary scanning system and a fixed ion beam path according to another aspect of the present invention.

FIGS. 3A and 3B demonstrates a plan view of a scanning arrangement according to conventional methods.

FIG. 4 illustrates a method for scanning a workpiece through a fixed ion beam according to another aspect of the present invention.

FIGS. 5A-5E demonstrate plan views of a scanning arrangement according to yet another aspect of the present invention.

FIG. 6. is a simplified perspective view of an exemplary reciprocating drive apparatus according to still another aspect of the present invention.

FIGS. 7-9 are simplified plan views of another exemplary two-dimensional scanning apparatus according to yet another aspect of the present invention.

### DETAILED DESCRIPTION OF THE INVENTION

The present invention will now be described with reference to the drawings wherein like reference numerals are used to refer to like elements throughout, and wherein the illustrated structures are not necessarily drawn to scale. The invention provides ion implantation systems to compensate for disadvantageous thermal conditions on a semiconductor workpiece, as well as methods for providing a workpiece to a fixed ion beam and/or a ribbon ion beam.

Although illustrated and described below in the context of exemplary low energy ion implantation systems, the invention may alternatively be employed in high or medium energy ion implanters, which may or may not include acceleration components.

Conventional high current and/or high-energy ion implantation applications typically result in an increase of workpiece temperature near the edge for a subsequent scan relative to a prior scan, thus causing non-uniform ion implantation results. The surface temperature of a workpiece is a function of the ion beam power and the technique used for ion beam scanning and/or workpiece scanning. Therefore, a need exists for a method for reducing a transient workpiece temperature during implantation.

Productivity in ion implantation systems is generally a function of several factors. For example, productivity can be quantified by a capability of the system to generate a particular amount of ion beam current, a ratio between a number of ions that are generated by the system to a number of ions actually implanted in the workpiece (e.g., a silicon wafer), or a ratio between an amount of time in which the workpiece is being implanted with ions and an amount of time taken for positioning the workpiece for ion implantation. The ratio of generated ions to ions actually implanted in the workpiece, for example, is generally referred to as “ion beam utilization”, as will be discussed hereafter.

For low dose ion implants (e.g., ion implantations having a dosage of less than approximately 1×10¹⁴ ions/cm²), a current of the ion beam typically ranges well below limitations in the capability of the ion implantation system, and the ion beam current can be increased in order to account for a potentially-low ion beam utilization. However, for high dose ion implants (e.g., ion implantations having a dosage of greater than approximately 1×10¹⁵ ions/cm²) as contemplated in the present invention, the ion beam current is typically at or near the maximum capability of the ion implantation system, and ion beam utilization has a much greater significance to the productivity of the system for optimal ion implantations. Such ion implantations are referred to as “beam current limited” implants, wherein the utilization of the ion beam is an important factor in determining the most advantageous usage of various types of ion implantation systems. For example, multiple-substrate ion implantation systems, or batch implanters, traditionally have a significantly higher ion beam utilization than single substrate systems, thus making the multiple-substrate systems the conventional tool of choice for high dose implants. However, single-substrate ion implantation systems, or serial systems, have various other advantages, such as contamination control, process lot size flexibility, and, in some configurations, incident beam angle control. Therefore, as contemplated by the inventors, it would be highly desirable for the single-substrate system to be utilized in a method that minimizes losses in productivity.

Therefore, the present invention is directed to an increase of thermal uniformity in a single-workpiece ion implantation system, wherein the workpiece transient temperature operating parameter is controlled by rotation of the workpiece between fixed beam scans. Rotating the workpiece between scans allows for the transient temperature of the workpiece surface to decay sufficiently for a more uniform ion implantation process to proceed along a scan axis.

In one embodiment of the present invention, several advantages over conventional methods using typical single-workpiece or single-wafer ion implantation systems are provided. For example, conventional single-workpiece ion implantation systems or serial implanters have generally fixed linear scan speeds and accelerations in one or more axes (e.g., in a slow-scan axis), and are not typically optimized for a uniform thermal continuum in a fixed ion beam. Control of transient thermal parameters during ion implantation reduces workpiece temperature.

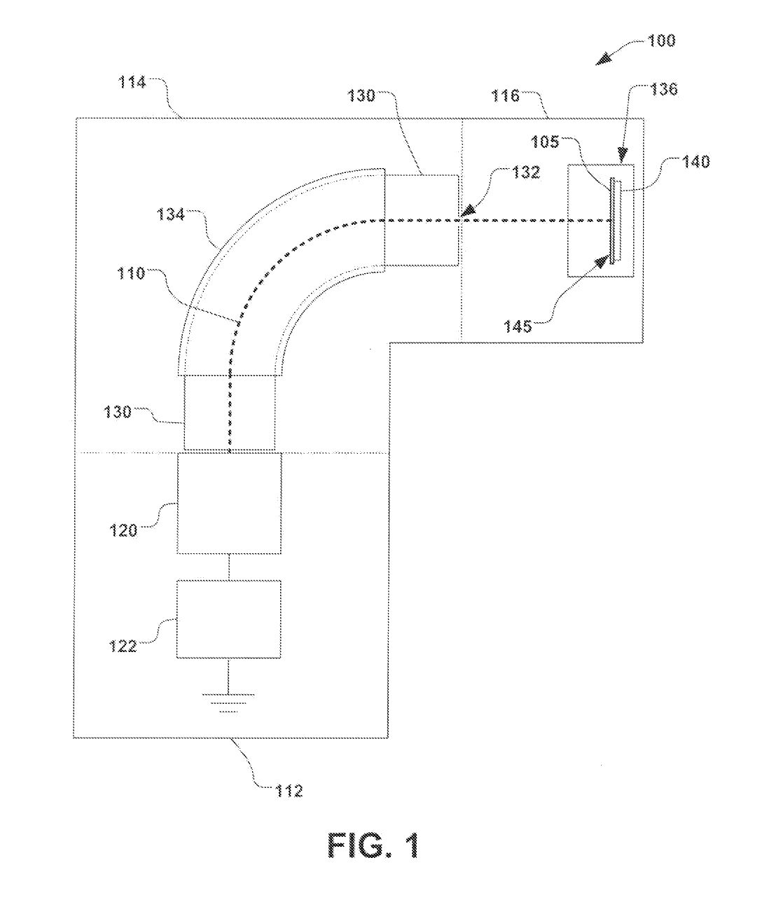

Referring now to the figures, in accordance with one exemplary aspect of the present invention, FIG. 1 illustrates an exemplary two-dimensional mechanically scanned single-workpiece ion implantation system 100, wherein the system is operable to mechanically scan a workpiece 105 through an ion beam 110. As stated above, various aspects of the present invention may be implemented in association with any type of ion implantation apparatus, including, but not limited to, the exemplary system 100 of FIG. 1. The exemplary ion implantation system 100 comprises a terminal 112, a beamline assembly 114, and an end station 116 that forms a process chamber in which the ion beam 110 is directed to a workpiece location. An ion source 120 in the terminal 112 is powered by a power supply 122 to provide the extracted ion beam 110 to the beamline assembly 114, wherein the source 120 comprises one or more extraction electrodes (not shown) to extract ions from the source chamber and thereby to direct the extracted ion beam 110 toward the beamline assembly 114.

The beamline assembly 114, for example, comprises a beamguide 130 having an entrance near the source 120 and an exit with a resolving aperture 134, as well as a mass analyzer 134 that receives the extracted ion beam 110 and creates a dipole magnetic field to pass only ions of appropriate energy-to-mass ratio or range thereof (e.g., a mass analyzed ion beam 110 having ions of a desired mass range) through the resolving aperture 132 to the workpiece 105 on a workpiece scanning system 136 associated with the end station 116. Various beam forming and shaping structures (not shown) associated with the beamline assembly 114 may be further provided to maintain and bound the ion beam 110 when the ion beam is transported along a beam path to the workpiece 105 supported on the workpiece scanning system 136.

The end station 116 illustrated in FIG. 1, for example, is a “serial” type end station that provides an evacuated process chamber in which the single workpiece 105 (e.g., a semiconductor wafer, display panel, or other workpiece) is supported along the beam path for implantation with ions.

According to one exemplary aspect of the present invention, the single-workpiece ion implantation system 100 provides a generally stationary ion beam 110 (e.g., also referred to as a “spot beam” or “pencil beam”), wherein the workpiece scanning system 136 generally translates the workpiece 105 in two generally orthogonal axes with respect to the stationary ion beam.

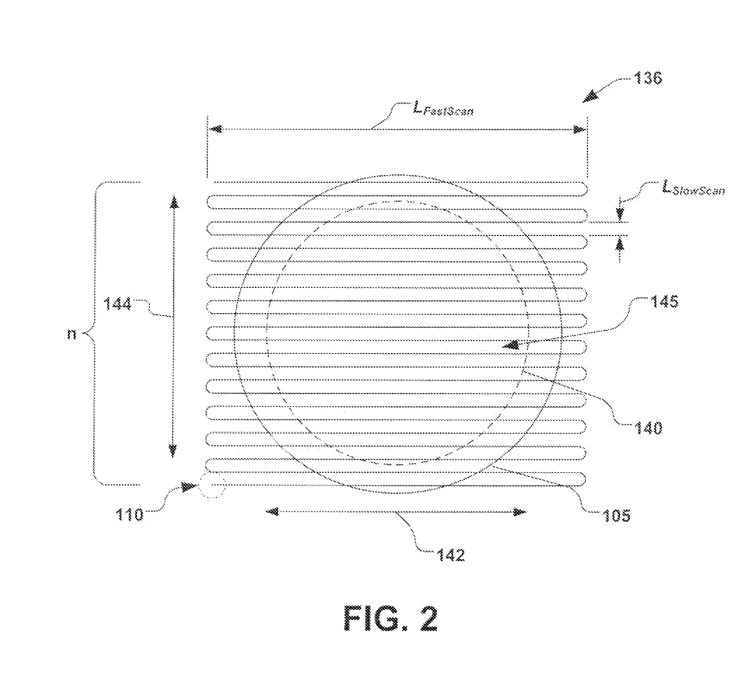

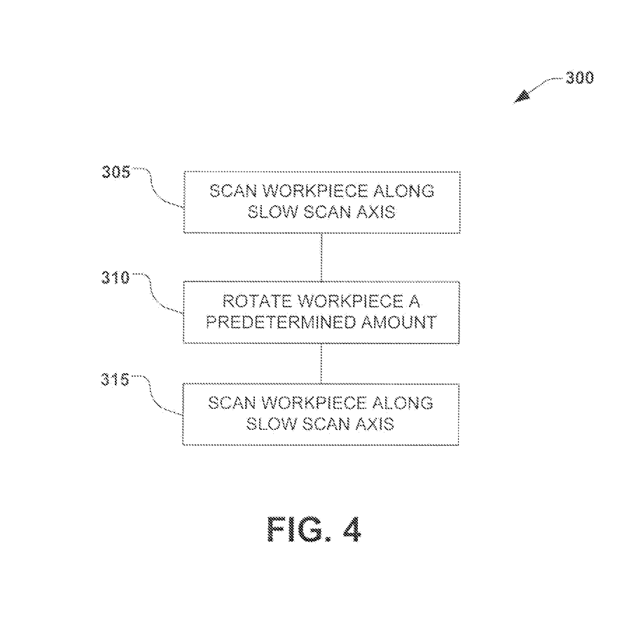

FIG. 2 illustrates a plan view of the exemplary workpiece scanning system 136 when viewed from the trajectory of the generally stationary ion beam 110. The workpiece scanning system 136, for example, comprises a movable stage 140 whereon the workpiece 105 resides, wherein the stage is operable to translate the workpiece along a fast scan axis 142 and a generally orthogonal slow scan axis 144 with respect to the ion beam 110. In one embodiment of the invention, the workpiece is scanned and then stepped up along the slow scan axis 144 for a subsequent scan in the fast scan axis 142, as illustrated. Alternatively, the scanning system 136 may be operable to scan the workpiece 105 along both axes 142 and 144 concurrently, thereby resulting in a zig-zag type scan pattern (for example, as illustrated in FIGS. 4A and 4B). One objective of the ion implantation system 100 of FIG. 1 is to provide both the correct dosage or number of ions to be implanted into the workpiece 105 from the ion beam 110, as well as to provide a uniformity of the ion implantation across a surface 145 of the workpiece.

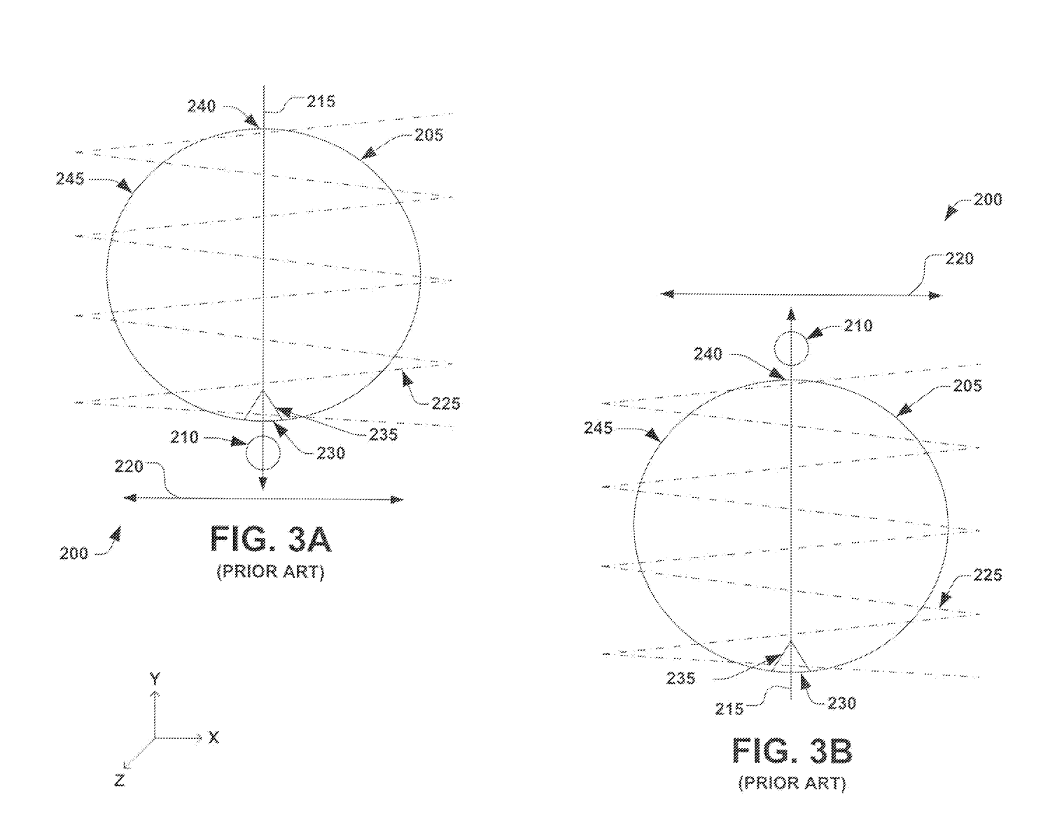

FIGS. 3A and 3B demonstrate a conventional two-dimensional scanning 200 of a workpiece 205 through a fixed ion beam 210, wherein the workpiece is first scanned along a slow scan axis 215 through the ion beam in the −y direction, as illustrated in FIG. 3A, and then in the +y direction, as illustrated in FIG. 3B. During the scanning of the workpiece 205 along the slow scan axis 215, the workpiece is further reciprocated along a fast scan axis 220, therein defining a relative path 225 taken by the workpiece with respect to the ion beam 210. Each traverse of the workpiece 205 through the ion beam 210 in one direction (e.g., the −y direction or the +y direction) is considered a “pass” or “scan” of the workpiece in that direction. Conventionally, the workpiece 205 makes at least two passes along the slow scan axis 215, namely, one pass in the −y direction, and one pass in the +y direction.

The translation of the workpiece 205 through the ion beam 210 generally defines a first edge 230 (e.g., illustrated with reference to a notch 235 in FIG. 3A), and a second edge 240 (e.g., illustrated as generally opposite the notch). Accordingly, as illustrated in FIG. 3A, the first edge 230 passes through the ion beam 210, followed by the second edge 240, when traveling in the −y direction. Conventionally, however, when traveling in the +y direction for the next scan along the slow scan axis 215, as illustrated in FIG. 3B, the second edge 240 of the workpiece 205 first passes through the ion beam 210, followed by the first edge 230. Thus, in the conventional scanning 200, the workpiece 205 maintains the same orientation 245 throughout both scans of FIGS. 3A and 3B. Consequently, the transient temperature of the first edge 230 of the workpiece 205 from an initial scan pass to a subsequent scan pass is small, relative to a large transient temperature at the second edge 240. Further, a time between slow scans (e.g., the time that the ion beam 210 does not intersect the workpiece 205 at the end of a pass) is greater at the first edge 230 than at the opposite second 240, thus causing a less uniform thermal continuum at the first edge.

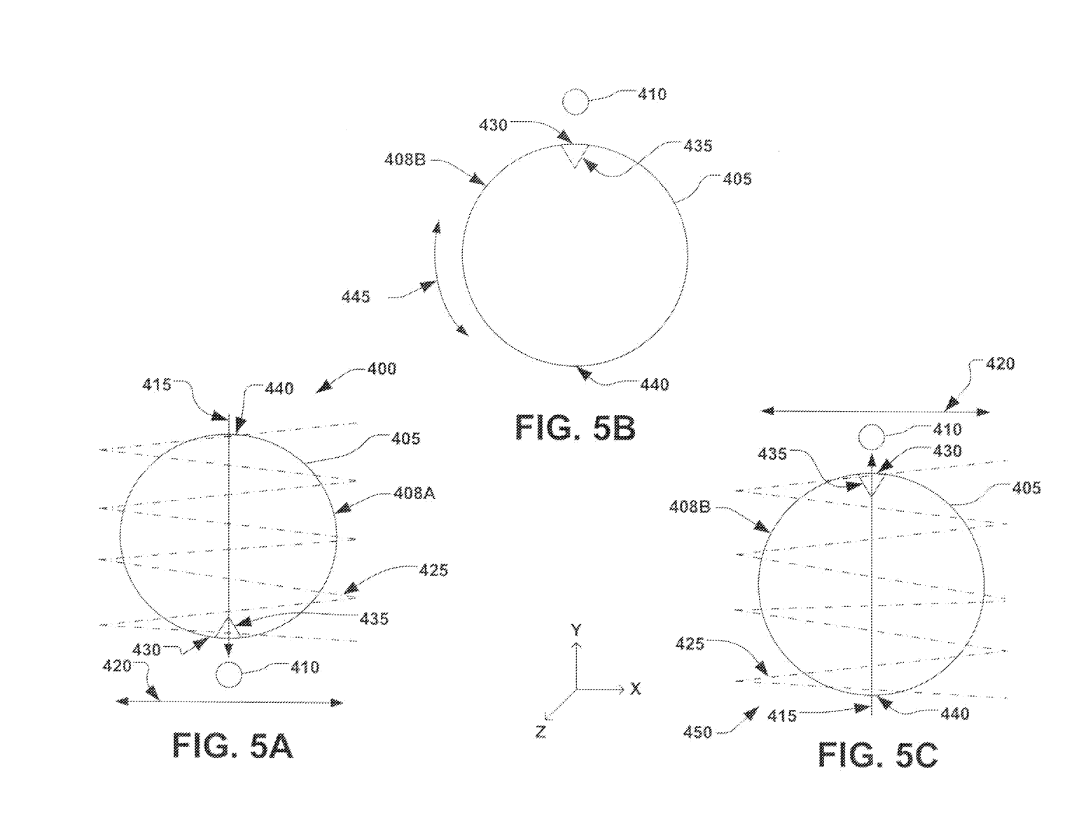

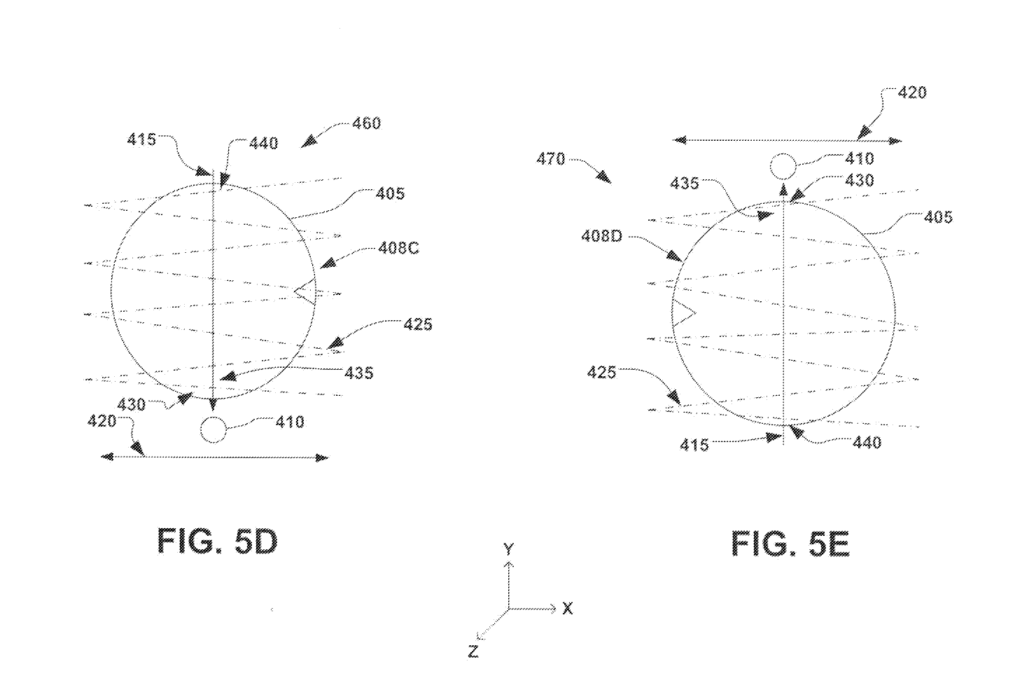

In accordance with the present invention, the disadvantageous thermal non-uniformity associated with the prior art is alleviated by a method 300 illustrated in FIG. 4. FIGS. 5A-5D, for example, illustrate various stages 400A-400D of processing according to the method 300 of FIG. 4, wherein a more uniform thermal continuum is achieved during ion implantation by changing an orientation of the workpiece. While example methods are illustrated and described herein as a series of acts or events, it will be appreciated that the present invention is not limited by the illustrated ordering of such acts or events, as some steps may occur in different orders and/or concurrently with other steps apart from that shown and described herein, in accordance with the invention. In addition, not all illustrated steps may be required to implement a methodology in accordance with the present invention. Moreover, it will be appreciated that the methods may be implemented in association with the systems illustrated and described herein as well as in association with other systems not illustrated.

As illustrated in FIG. 4, the method 300 comprises scanning the workpiece in the y scan direction (e.g., along the slow scan axis) through a generally stationary ion beam in act 305, when the workpiece is in a first orientation, therein defining a first scan of the workpiece through the ion beam. For example, act 305 is illustrated in FIG. 5A, wherein a first scan 400 of the workpiece 405 in a first orientation 408A is performed, wherein the workpiece is scanned through the generally stationary ion beam 410. The workpiece 405, for example, is scanned along the slow scan axis 415 in the −y direction (e.g., the first scan 400), while further being scanned or reciprocated along the fast scan axis 420, and while generally maintaining the first orientation 408A, thus defining a scan path 425. A first edge 430 (e.g., associated with notch 435) of the workpiece 405 passes through the ion beam 410 first in the first scan, followed by a second edge 440 upon completion of the scan in the −y direction.

After the initial mechanical scan (i.e., the first scan) of the workpiece 405 along the slow scan axis 415 (e.g., in the −y direction) of act 305 of FIG. 4, the workpiece is rotated a first predetermined amount (e.g., approximately 180 degrees) in act 310 to be at a second orientation. FIG. 5B illustrates the rotation 445 that is performed by a rotating means (not shown) after the first scan in the −y direction, wherein the workpiece is placed in the second orientation 408B prior to a subsequent scan. Thus, in act 315 of FIG. 4, the workpiece is scanned in the +y scan direction along the slow scan axis through the generally stationary ion beam in act 305, when the workpiece is in second orientation, therein defining a second scan of the workpiece through the ion beam. FIG. 5C illustrates a second scan 450 of the workpiece 405 in the +y scan direction along the slow scan axis 415. Thus, in accordance with an aspect of the present invention, the first edge 430 of the workpiece 405 is at the leading edge of the subsequent scan (the second scan 450, in this example), wherein sufficient time is provided for temperatures at each edge (the first edge 430 and second edge 440) to dissipate uniformly to allow for uniform ion implantation.

According to another example, such as when implanting hydrogen ions into the workpiece, the workpiece 405 is rotated a second predetermined amount (e.g., approximately 90 degrees) and placed in a third orientation 408C after the second scan, as illustrated in FIG. 5D. A third scan 460 of the workpiece 405 through the ion beam 410 in the −y scan direction along the slow scan axis 415 is again performed. After the third scan 460, the workpiece 405 is again rotated the first predetermined amount (e.g., approximately 180 degrees), and is again passed through the ion beam in the +y scan direction, therein defining a fourth scan 470 of the workpiece, as illustrated in FIG. 5E. Accordingly, temperature uniformity across the workpiece can be maintained. It should be noted that any number of scans of the workpiece 405 can be implemented according to the present invention, as well as any intervening degree(s) of rotation between scans, wherein ion implantation uniformity is improved over conventional scanning methodologies. Accordingly, all such number of scans and rotations are contemplated as falling within the scope of the present invention.

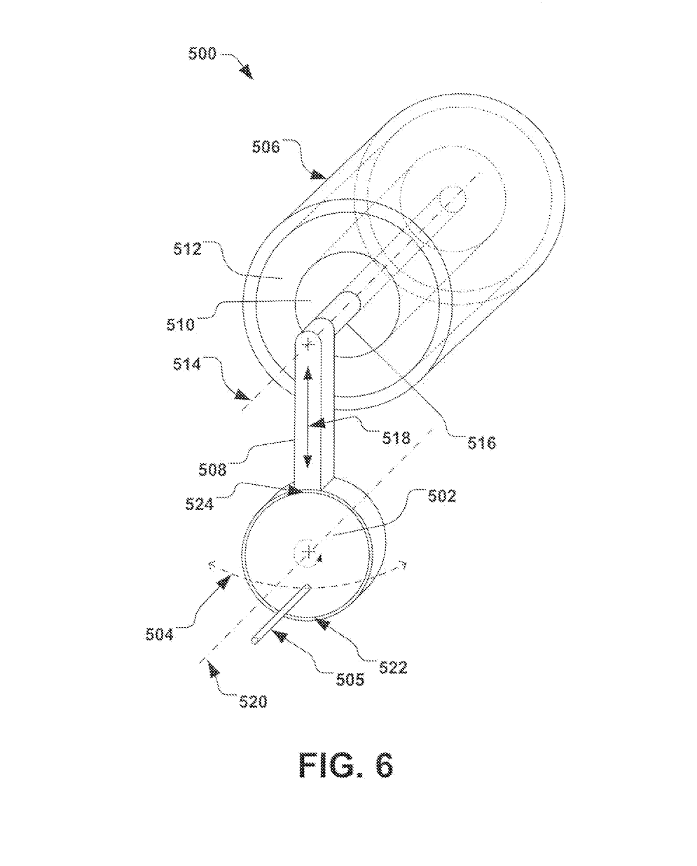

FIG. 6 illustrates a simplified perspective view of an exemplary reciprocating drive apparatus 500 operable to reciprocally translate or oscillate a workpiece 502 along a predetermined first scan path 504. It should be noted that the reciprocating drive apparatus 500 of FIG. 6 is illustrated to provide an upper-level understanding of the invention, and is not necessarily drawn to scale. Accordingly, various components may or may not be illustrated for clarity purposes. It shall be understood that the various features illustrated can be of various shapes and sizes, or excluded altogether, and that all such shapes, sizes, and exclusions are contemplated as falling within the scope of the present invention.

As implied by the use of the term “reciprocating drive apparatus”, in one example, the drive apparatus of the present invention is operable to reciprocally translate or oscillate the workpiece 502 in a reversible motion along the first scan path 504, such that the workpiece translates alternatingly back and forth with respect to a generally stationary ion beam 505, wherein the apparatus can be utilized in an ion implantation process. Alternatively, the reciprocating drive apparatus 500 may be utilized in conjunction with various other processing systems, which may include other semiconductor manufacturing processes such as, for example, a step-and-repeat lithography system.

According to one aspect of the present invention, the reciprocating drive apparatus 500 comprises a motor 506 operably coupled to a scan arm 508 wherein the scan arm is further operable to support the workpiece 502 thereon. The motor 506, for example, comprises a rotor 510 and a stator 512, wherein the rotor and the stator are dynamically coupled and operable to individually rotate about a first axis 514. The rotor 510 is further operably coupled to a shaft 516, wherein the shaft generally extends along the first axis 514 and is operably coupled to the scan arm 508. In the present example, the rotor 510, shaft 516, and scan arm 508 are generally fixedly coupled to one another, wherein rotation of the rotor about the first axis 514 generally drives rotation of the shaft and scan arm about the first axis, thus generally translating the workpiece 502 along the first scan path 504. Alternatively, the rotor 510, shaft 516, and scan arm 508 may be otherwise coupled to one another, wherein the rotation of the rotor and/or shaft may drive a linear translation of the scan arm with respect to the first axis 514.

As can be appreciated, the system 500 is operable to reciprocate the workpiece 502 along scan path 504 that comprises a fast scan path. In addition, the entire system 500 is further operable to translate linearly along a second scan path or axis 518, that comprises the slow scan path. According to an aspect of the present invention, the system 500 is further operable to rotate the workpiece 502 a predetermined amount (e.g., between 0 and 360 degrees) about a workpiece axis 520 after one scan along the second scan path 518 prior to returning in the opposite direction along the second scan path. In the above manner, for example, when rotated 180 degrees, a first edge 522 of the workpiece remains the leading edge and a second edge 524 remains the lagging edge for the scans along the second scan path 518 in differing directions, thereby improving thermal uniformity in scan conditions.

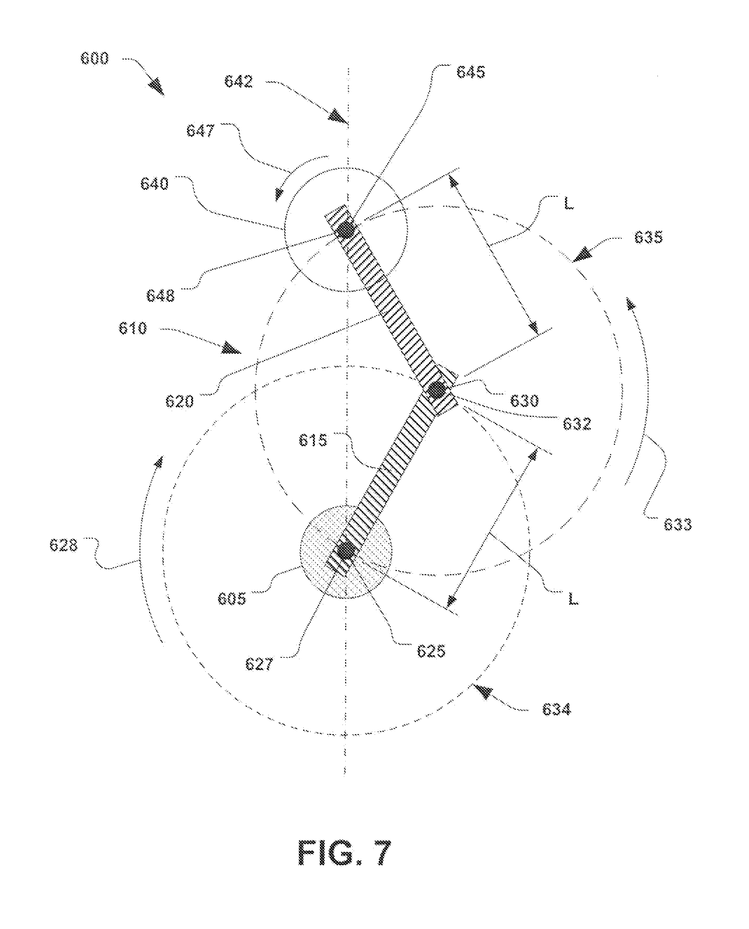

FIG. 7 illustrates an exemplary scanning mechanism 600 or end station according to one embodiment of the present invention. The scanning mechanism 600, for example, may be further associated with an ion beam for use in an ion implantation process of the present invention. It should be noted that the present invention may be utilized in conjunction with various semiconductor processing systems, and all such systems are contemplated as falling within the scope of the present invention. The scanning mechanism 600, for example, comprises a base portion 605 operably coupled to a rotary subsystem 610. The base portion 605, for example, may be operable to move with respect to the beam, as will be discussed hereafter. The rotary subsystem 610 comprises a first link 615 and a second link 620 associated therewith, wherein, for example, the rotary subsystem is operable to translate a workpiece (not shown) with respect to the base portion 605 via a predetermined movement of the first link and the second link.

According to one example, the first link 615 is rotatably coupled to the base portion 605 via a first joint 625, wherein the first link is operable to continuously rotate about a first axis 627 in a first rotational direction 628 (e.g., the first link is operable rotate clockwise or counter-clockwise with respect to the first joint). The second link 620 is further rotatably coupled to the first link 615 via a second joint 630, wherein the second joint is spaced a predetermined distance L from the first joint 625. The second link is further operable to continuously rotate about a second axis 632 in a second rotational direction 633 (e.g., the second link is operable to rotate clockwise or counter-clockwise with respect to the second joint). The first link 615 and the second link 620, for example, are further operable to rotate in separate, yet generally parallel first and second planes (not shown), respectively, wherein the first and second planes are generally perpendicular to the respective first and second axes 627 and 632. Furthermore, the first link 615 and second link 620 are operable to continuously rotate 360° in a respective first rotational path 634 and second rotational path 135 about the respective first joint 625 and second joint 630.

According to one exemplary aspect of the invention, the first rotational direction 628 is generally opposite the second rotational direction 633, wherein an end effector 640 associated with the second link 620 is operable to linearly translate along a first scan path 642 (e.g., a fast scan path) associated with the predetermined movement of the first link 615 and the second link. The end effector 640, for example, is operably coupled to the second link 620 via a third joint 645 associated with the second link, wherein the third joint is spaced the predetermined distance L from the second joint 630. The third joint 645, for example, is operable to provide a rotation 647 of the end effector 640 about a third axis 648. Furthermore, according to another example, the third joint 645 is further operable to provide a tilt (not shown) of the end effector 640, wherein, in one example, the end effector is operable to tilt about one or more axes (not shown) which are generally parallel to the second plane (not shown).

The end effector 640, for example, is further operable to secure the workpiece 646 thereto, wherein the movement of the end effector generally defines a movement of the workpiece. The end effector 640, for example, may comprise an electrostatic chuck (ESC), wherein the ESC is operable to substantially clamp or maintain a position of the workpiece 646 with respect to the end effector. It should be noted that while an ESC is described as one example of the end effector 640, the end effector may comprise various other devices for maintaining a grip of a payload (e.g., the workpiece), and all such devices are contemplated as falling within the scope of the present invention.

The predetermined movement of the first link 615 and second link 620, for example, can be further controlled in order to linearly oscillate the end effector 640 along the first fast scan path 642, wherein the workpiece (not shown) can be moved in a predetermined manner with respect to the ion beam (e.g., an ion beam coincident with the first axis 627). A rotation of the third joint 645, for example, can be further controlled, wherein the end effector 640 is maintained in a generally constant rotational relation with the first fast scan path 642 when traveling therealong. It should be noted that the predetermined distance L separating the first joint 625 and second joint 630, as well as the second joint and third joint 645, provides a general congruity in link length when measured between the respective joints. Such a congruity in length of the first link 615 and second link 620, for example, generally provides various kinematic advantages.

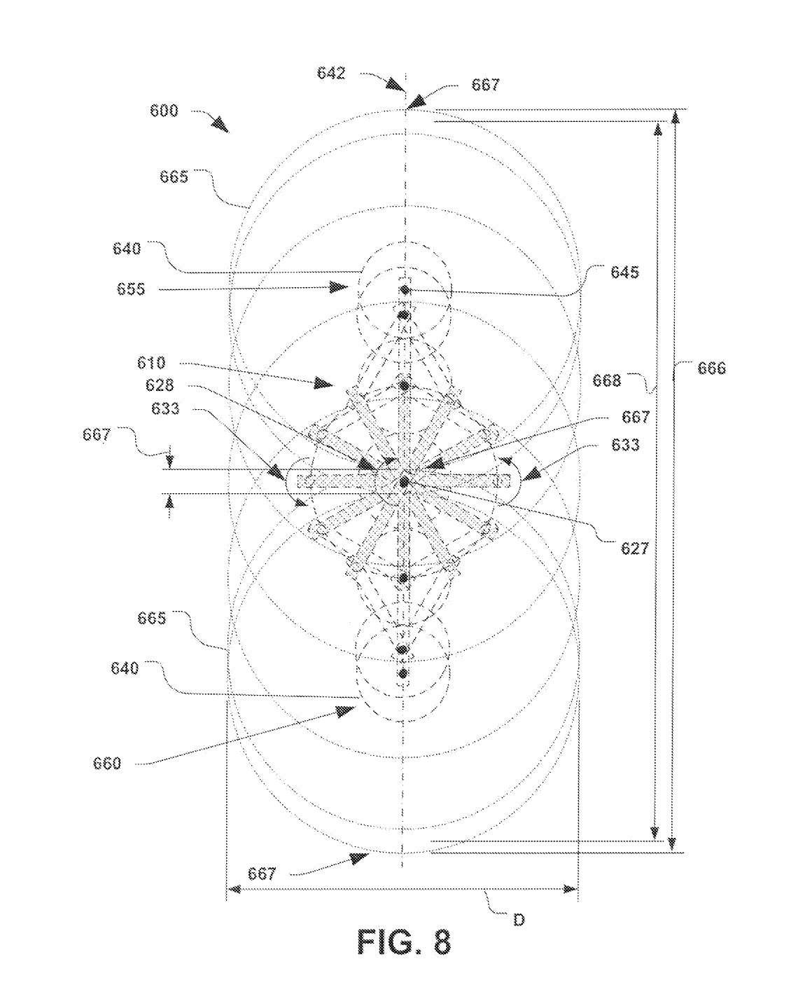

As illustrated in FIG. 8, the scanning mechanism 600 is operable to linearly oscillate a workpiece 665 along the first fast scan path 642 between maximum positions 655 and 660 of the end effector 640. Therefore, a maximum scan distance 166 traveled by opposite ends 667 of the workpiece 665 can be generally defined along the fast scan path 642 (e.g., opposite ends of the circumference of the workpiece along the first scan path), wherein the maximum scan distance is associated with the maximum positions 655 and 660 of the end effector 640. According to one exemplary aspect of the invention, the maximum scan distance 666 is greater than twice a diameter D of the workpiece 665. The amount by which the maximum scan distance 666 is greater than twice the diameter D is defined as an overshoot 667. The overshoot 667, for example, can be advantageously utilized when the oscillation of the workpiece 665 along the first scan path 642 changes directions.

It should be therefore noted that while the rotational directions 628 and 633 remain constant (i.e., unchanged), the movement of the end effector 640 and workpiece 665 oscillates along the first scan path 642, thus changing direction at the maximum positions 655 and 660. Such a change in direction of the end effector 640 (and hence, the workpiece 665) is associated with a change in velocity and acceleration of the end effector and workpiece. In ion implantation processes, for example, it is generally desirable for the end effector 640 to maintain a substantially constant velocity along the scan path 642 when the workpiece 665 passes through an ion beam (not shown), such as an ion beam which is generally coincident with the first axis 627. Such a constant velocity provides for the workpiece 665 to be generally evenly exposed to the ion beam throughout the movement through the ion beam. However, due to the oscillatory motion of the end effector 640, acceleration and deceleration of the end effector is inevitable; such as when the third joint 645 (e.g., associated with the end effector and workpiece 665) approaches the maximum positions 655 and 660 at either extent of the linear oscillation. Such an acceleration and deceleration near the maximum positions 655 and 660 (e.g., during scan path turn-around), should be maintained at reasonable levels in order to minimize inertial forces and associated reaction forces transmitted to the base portion 605 of the scanning mechanism 600. Variations in velocity of the end effector 640 during exposure of the workpiece 665 to the ion beam, for example, can lead to a non-uniform ion implantation across the workpiece.

Therefore, a generally constant velocity is desired for a predetermined range 668 associated with the movement of the workpiece 665 through the ion beam. For example, the predetermined range 168 is associated with the physical dimensions of the workpiece 665 (e.g., twice a diameter of the workpiece), such that the acceleration and deceleration of the end effector can be generally accommodated within the overshoot 667. Accordingly, once the workpiece 665 completely passes through the ion beam, the acceleration and deceleration of the end effector 640 will not substantially affect an ion implantation process or dose uniformity across the workpiece.

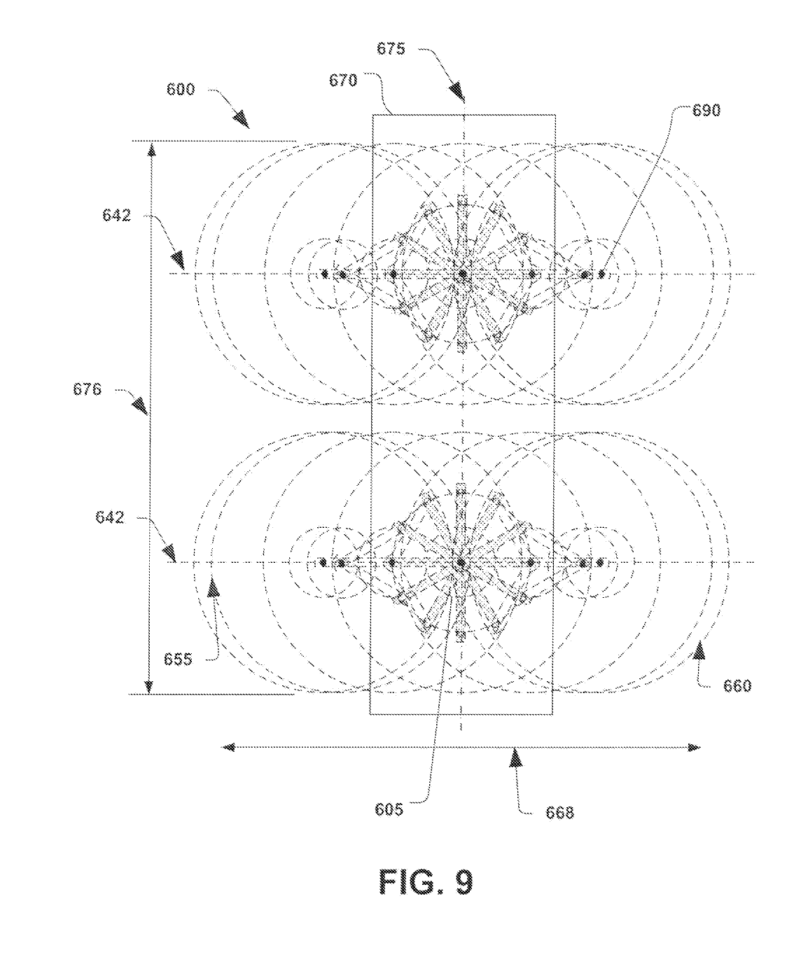

FIG. 9 illustrates another exemplary aspect of the present invention, wherein the base portion 605 of the scanning mechanism 600 is further operable to translate in one or more directions. For example, the base portion 605 is operably coupled to a translation mechanism 670, wherein the translation mechanism is operable to translate the base portion and rotary subsystem along a second slow scan path 675, wherein the second scan path is substantially perpendicular to the first scan path 642. According to one exemplary aspect of the invention, the first scan path 642 is associated with a fast scan of the workpiece 665, and the second slow scan path 675 is associated a slow scan of the workpiece, wherein the workpiece is indexed one increment along the second scan path for every translation of the workpiece between maximum positions 655 and 660 along the first fast scan path. Therefore, for a full oscillation of the workpiece 665 along the first scan path 642, the translation mechanism 670 will translate the workpiece two increments along the second slow scan path 675. A total translation 676 of the base portion, for example, is approximately the diameter D of the workpiece 665. The translation mechanism 670 of FIG. 9, for example, may further comprise a prismatic joint. The translation mechanism 670 may still further comprise a ball screw system (not shown), wherein the base portion 605 can be smoothly translated along the second scan path 675. Such a translation mechanism 670, for example, is operable to “paint” the workpiece 665 residing on the end effector 640 by passing the workpiece through the ion beam in an incremental manner during the oscillation of the end effector, thus uniformly implanting ions across the entire workpiece.

The present invention may be employed in conjunction with the system of FIG. 9, wherein after one pass along the slow path 675, the workpiece 665 is rotated about a workpiece axis 690 normal to the surface thereof (e.g., approximately 180 degrees) prior to returning along the slow scan path in the opposite direction.

Although the invention has been illustrated and described with respect to one or more implementations, alterations and/or modifications may be made to the illustrated examples without departing from the spirit and scope of the appended claims. In particular regard to the various functions performed by the above described components or structures (blocks, units, engines, assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

What is claimed is:

1. A method of implanting ions into a workpiece, the method comprising:
providing a mass analyzed fixed ion beam along a beam path;
directing the ion beam toward the workpiece;
scanning the workpiece in a first direction along a slow scan axis through the ion beam from a first edge to a second edge of the workpiece; and
rotating the workpiece for a subsequent scan through the ion beam in a second direction generally opposite the first direction along the slow scan axis to begin the subsequent scan at the first edge of the workpiece.

2. The method of claim 1, wherein at least two scans of the workpiece are performed along the slow scan axis with at least one rotation of the workpiece intervening an initial scan and a subsequent scan.

3. The method of claim 1, wherein the workpiece is rotated 180 degrees.

4. The method of claim 1, wherein scanning the workpiece in the first direction comprises scanning the workpiece past the second edge, wherein the ion beam does not intersect the workpiece, and wherein the workpiece is rotated when the ion beam does not intersect the workpiece.

5. The method of claim 1, wherein the workpiece is a substrate of a semiconductor wafer.

6. An ion implantation system, comprising:
an ion source operable to produce an ion beam;
a mass analyzer receiving the ion beam from the ion source and providing a mass analyzed ion beam comprising ions of a desired mass range along a beamline axis; and
an end station configured to scan a workpiece through the ion beam along a fast scan axis and a slow scan axis, comprising a rotational mechanism configured to rotate the workpiece a predetermined amount about an axis parallel to the beamline axis between each slow scan.

7. The ion implantation system of claim 6, wherein the ion beam is a fixed ion beam.

8. The ion implantation system of claim 7, wherein the ion beam comprises one or more of a spot ion beam and a ribbon beam.

9. The ion implantation system of claim 6, wherein the predetermined amount is approximately 180 degrees.

10. An apparatus for ion implantation of a workpiece, comprising:
a means for generating an ion beam for implantation of ions into a workpiece;
a means for reciprocating the workpiece in a first direction orthogonal to a second direction so as to traverse to and fro through the ion beam; and
a means for rotating the workpiece about a beamline axis between each successive scan along a slow scan axis of the wafer through the ion beam.

11. The apparatus of claim 10, wherein the ion beam is a fixed ion beam.

12. The apparatus of claim 11, wherein the ion beam comprises one or more of a spot ion beam and a ribbon beam.

13. The apparatus of claim 10, wherein the means for rotating the workpiece is configured to rotate the workpiece a predetermined amount.

14. The apparatus of claim 9, wherein the predetermined amount is approximately 180 degrees.

15. A method of implanting ions into a workpiece, the method comprising:
providing a fixed ion beam;
scanning the workpiece through the fixed ion beam in a first direction along a slow scan axis, therein defining a first scan pass;
rotating the workpiece a first predetermined amount after the first scan pass; and
scanning the workpiece through the fixed ion beam in a second direction along the slow scan axis, therein defining a second scan pass, wherein the second direction is generally opposite of the first direction.

16. The method of claim 15, wherein the first predetermined amount is approximately 180 degrees.

17. The method of claim 16, further comprising:
rotating the workpiece a second predetermined amount after the second scan pass;
scanning the workpiece through the fixed ion beam in the first direction along the slow scan axis, therein defining a third scan pass;
rotating the workpiece the first predetermined amount; and
scanning the workpiece through the fixed ion beam in the second direction along the slow scan axis, therein defining a fourth scan pass.

18. The method of claim 17, wherein the second predetermined amount is approximately 90 degrees.

19. The method of claim 17, wherein the fixed ion beam comprises ions of hydrogen.
